(19) United States
(12) Patent Application Publication
(10) Pub. No.: US 2026/0349059 A1
(43) Pub. Date: Nov. 5, 2026

(54) Fast Evaluation of High Order Phase Transforms using Learnable Fourier Kernels for Efficient Field Correction in MRI

(71) Applicant: The Board of Trustees of the Leland Stanford Junior University, Stanford, CA (US)

(72) Inventors: Daniel Raz Abraham, Palo Alto, CA (US); Kawin Setsompop, Stanford, CA (US); Mark Nishimura, Sunnyvale, CA (US); John M. Pauly, Stanford, CA (US)

(21) Appl. No.: 19/655,460

(22) Filed: Apr. 22, 2026

Related U.S. Application Data
(60) Provisional application No. 63/792,738, filed on Apr. 22, 2025.

(51) Int. Cl. G01R 33/56; G01R 33/48

(52) U.S. Cl. CPC G01R 33/5608; G01R 33/482; G01R 33/4824

(57) ABSTRACT

A method for magnetic resonance imaging (MRI) acquires k-space data and measures non-linear spatio-temporal phase coefficients, then constructs combined spatio-temporal phase coefficients using the measured non-linear spatio-temporal phase coefficients and vector deviations of the k-space data coordinates from nearest Cartesian grid points. Time-varying kernel weights and their respective spatial factors are then jointly trained to model the combined spatio-temporal phase coefficients. A high order FFT forward model relating an input image to the k-space data is constructed and then used to solve a general linear inverse problem to obtain a reconstructed MRI image from the acquired k-space data. Constructing the forward model includes: computing an oversampled FFT of the input image multiplied by the spatial factors, selecting grid points that are nearest to Cartesian grid points, and performing a dot product between the time-varying kernel weights and the values at the selected grid points for each of the spatial factors to obtain high-order phase modeled k-space data.

### CROSS-REFERENCE TO RELATED APPLICATIONS

This application claims priority from U.S. Provisional Patent Application 63/792,738 filed Apr. 22, 2025, which is incorporated herein by reference.

### STATEMENT REGARDING FEDERALLY SPONSORED RESEARCH OR DEVELOPMENT

This invention was made with Government support under EB019437, EB025162, EB030006, EB033206, MH116173, and NS129893 awarded by the National Institutes of Health. The Government has certain rights in the invention.

### FIELD OF THE INVENTION

The present invention relates generally to magnetic resonance imaging (MRI). More specifically, it relates to image reconstruction techniques that correct for artifacts due to field imperfections caused by the use of long-readout trajectories during image acquisition.

### BACKGROUND OF THE INVENTION

Long-readout MRI sequences operate in a regime of extended, continuous data acquisition. This regime offers improved SNR efficiency and enables more efficient k-space encoding strategies. Trajectories designed for this setting, including EPI, spirals, cones, and rosettes, achieve high encoding efficiency and can often reconstruct an image in a single shot or volumetric data with far fewer shots. Beyond reducing overall scan time, such approaches are key to enabling high temporal resolution imaging, which is essential for capturing complex physiological dynamics.

Unfortunately, using highly efficient long-readout trajectories increases the sensitivity to field imperfections, resulting in image artifacts. These artifacts can be corrected if the field imperfections are properly estimated and modeled in the image reconstruction process. Several techniques exist to robustly estimate field imperfections, such as using external NMR field probe hardware or estimating spatio-temporal fields from MRI calibration signals. However, techniques to incorporate the known field imperfections into an image reconstruction are extremely computationally expensive. Clinical translation of such long-readout trajectories is contingent on being able to reconstruct images at speeds comparable to data acquisition speeds (minutes). Currently, reconstruction of images in the presence of field imperfections takes anywhere from tens of minutes to several hours.

### BRIEF SUMMARY OF THE INVENTION

The present invention improves the computational efficiency of field correction in MRI. Doing so involves speeding up the evaluation of higher order phase transforms; which are an extension of Fourier transforms but with spatially non-linear (instead of spatially linear) phase. The non-linear phase patterns stem from the underlying field imperfections.

Our technique is up to an order of magnitude faster than existing techniques for modeling these types of fields, while requiring much less memory resources. There are various commercial applications of this technique. Research facilities can use this to achieve rapid images in near real-time for field-sensitive research applications such as fMRI, or Diffusion weighted images. MRI Clinicians can use this to enable fast scans and reconstructions in the clinic. Companies such as Skope can use this technique to dramatically improve their reconstruction pipeline.

The technique of the present invention builds upon previous techniques that handle spatially linear phase—i.e. a Fourier transform. In order to model the non-uniform Fourier transform of a discrete image x(r), defined on a grid of spatial coordinates r, the Non-Uniform Fast Fourier Transform (NUFFT) algorithm can be used to compute the frequency domain samples X(k) at arbitrary non-uniform frequency domain coordinates k. This works by first computing an oversampled FFT on the discrete image x(r) to obtain a discrete grid of Fourier transform values X(z_{grid}). Then, any non-grid point X(k) can be written as a linear combination of nearby grid points X(z_{grid}). The linear combination coefficients can be determined analytically using common kernels in signal processing. We refer to the linear combination coefficients as a kernel. The kernel weights vary according to the vector deviation k_{dev} of the off-grid sample k to the nearest grid point z_{grid} (i.e., k_{dev}=k−z_{grid}). Importantly, the kernel size is compact, allowing for a computational efficient algorithm to estimate non-grid frequency domain samples from gridded ones.

Instead of using analytical kernels for linear phases as used in NUFFTs, embodiments of the invention represent the kernel weights using a Multi-Layer-Perceptron (MLP). These kernel weights are trained to handle spatially non-linear phases in addition to the linear phases. In the NUFFT linear phase example, the MLP would take as input the deviation coordinates k_{dev} and output the required kernel weights. The network can be trained efficiently offline, and can further be improved by training online with an image mask. To extend the MLP towards non-linear (high order) phases, the only modifications to be made are the training procedure and network input/outputs. The inputs will now be a combination of k_{dev} and the concatenated high order phase coefficients α giving a new vector [k_{dev}, α]. The kernels are usually small patches in the frequency domain, having sizes of 3×3, 4×4, 5×5, etc. Thus, for some high order phases with many phase wraps, these small kernels will not be sufficient. To remedy this, we add a separate dimension to the kernels so that they are e.g., 4×4×L where L is the number of spatial maps that are multiplied by the image before the FFT is applied. There exist methods to choose the L spatial maps, often referred to in the literature as time segmentation maps, frequency segmentation maps, or SVD spatial bases for field correction. These L spatial maps, also referred to as spatial factors, can be jointly trained when optimizing the kernel weights, also referred to as temporal factors.

To summarize, according to one embodiment, the pipeline to efficiently evaluate a high order phase transform involves the following:
1. Before Reconstruction: Obtain a description of the vector deviations k_{dev} and the non-linear spatio-temporal phase coefficients φ(r), α(t), decide on the kernel size.
2. Before Reconstruction (Optional): Initialize spatial maps that provide a subspace for the possible non-linear phases b₁(r), . . . , b_{L}(r).
3. Before Reconstruction: Train over all [k_{dev}, α] so that the MLP(k_{dev}, α) minimizes errors between the estimated phase (obtained by applying the kernels weights to their respective spatial functions), and the true desired phase over all voxels.
4. During Reconstruction: Compute an oversampled FFT of the image x(r), optionally x(r) is multiplied by several spatial maps b₁(r), . . . , b_{L}(r).
5. During Reconstruction: Select the nearest grid points within the kernel's size, and perform a dot product between the kernel weights and the values at the nearest grid points (integrate over L dimension if necessary) to obtain the desired high order phase transform value.

In one aspect, the invention provides a method for magnetic resonance imaging (MRI) implemented by an MRI apparatus. The method includes: (a) performing by an MRI apparatus an MRI acquisition using a readout sequence to produce acquired k-space data at coordinates k(t); (b) measuring by the MRI apparatus or field measurement equipment nonlinear spatio-temporal phase coefficients α(t), φ(r); (c) combining vector deviations k_{dev}(t) of the coordinates k(t) from nearest Cartesian grid points z_{grid}(t) with the measured nonlinear spatio-temporal phase coefficients α(t), φ(r) to construct combined spatio-temporal phase coefficients \tilde{φ}(r), \tilde{α}(t); (d) jointly training L time-varying kernel weights h_{HOFFT}(w, l, t) and their respective L spatial factors bₗ(r) to model the combined spatio-temporal phase coefficients \tilde{α}(t), \tilde{φ}(r); (e) constructing a HOFFT forward model A_{HOFFT} relating an input image x(r) to the k-space data y_{HOFFT}(t); and (f) solving a general linear inverse problem using A_{HOFFT} and the acquired k-space data to obtain a reconstructed MRI image. The MRI image may be stored and/or displayed by the MRI apparatus for diagnostic purposes.

The constructing of the HOFFT forward model includes: (i) computing an oversampled FFT of the input image x(r) multiplied by all L spatial factors bₗ(r); (ii) selecting grid points that are nearest to Cartesian grid points z_{grid}(t); and (iii) performing a dot product between the L time-varying kernel weights h_{HOFFT}(w, l, t) and the values at the selected grid points for each of the L spatial factors bₗ(r) to obtain high-order phase modeled k-space data y_{HOFFT}(t)=A_{HOFFT}{x(r)}.

In one implementation, jointly training comprises minimizing a difference between estimated and true total high order and non-Cartesian linear phase, wherein the estimated phase is obtained by applying kernel weights to respective spatial factors. In another implementation, h_{HOFFT}(w, l, t), bₗ(r) are represented using any optimizable signal representation approach. In another implementation, jointly training comprises training an MLP with a stochastic gradient descent optimizers. In another implementation, jointly training comprises training a grid-based representation with an alternating least squares optimizer.

### BRIEF DESCRIPTION OF THE SEVERAL VIEWS OF THE DRAWINGS

FIG. 1 shows a convolutional NUFFT pipeline.

FIG. 2 shows a HOFFT pipeline, according to an embodiment of the invention.

FIG. 3A shows 3×3 gridding kernel and corresponding apodization learned using the HOFFT framework, according to an embodiment of the invention.

FIG. 3B shows 4×4 gridding kernel and corresponding apodization learned using the HOFFT framework, according to an embodiment of the invention.

FIG. 4A shows spiral phantom measurements acquired in the presence of a concomitant and B₀ fields, yielding a spatio-temporal phase pattern, uncorrected reconstructions, reconstructions with 5 time-segments using optimal least squares interpolators and NUFFT kernels, and 5 time-segments using synergetic 9×9 HOFFT kernels, according to an embodiment of the invention.

FIG. 4B shows spiral in-vivo measurements are acquired in the presence of a physiologically induced field imperfection, yielding a physiological phase pattern, uncorrected reconstructions, reconstructions with 5 time-segments using optimal least squares interpolators and NUFFT kernels, and 5 time-segments using synergetic 9×9 HOFFT kernels, according to an embodiment of the invention.

FIG. 5A shows graphs of normalized root mean squared error (NRMSE) versus the number of time-segments for spiral phantom measurements acquired in the presence of a concomitant and B₀ fields, according to an embodiment of the invention.

FIG. 5B shows graphs of normalized root mean squared error (NRMSE) versus the number of time-segments for spiral in-vivo measurements are acquired in the presence of a physiologically induced field imperfection, according to an embodiment of the invention.

### DETAILED DESCRIPTION OF THE INVENTION

Magnetic Resonance Imaging (MRI) is a powerful imaging modality capable of resolving high resolution, diagnostically relevant images from a non-invasive data acquisition procedure. Spatial encoding in MRI relies on gradient coils engineered to generate spatially linear magnetic fields, which produce linear phase modulations and form the basis of the familiar k-space forward model. However, the encoding fields present during data acquisition are almost never spatially linear. Magnetic field imperfections in the form of main field inhomogeneities, concomitant fields, and induced eddy current fields are the most common culprits for such spatially non-linear fields. On modern MRI scanners, where the gradient fields are far stronger than the aforementioned field imperfections, imaging sequences that use short data acquisition bursts are typically insensitive to such field imperfections. However, similar to a conventional camera, there are Signal-to-Noise-Ratio (SNR) benefits to prolonging the data acquisition burst duration. Such SNR efficient sequences are far more sensitive to underlying magnetic field imperfections and hence have limited use in the clinic today. These field imperfections are exasperated on high gradient performance and high field systems, impeding scanner hardware from reaching its full potential. Additionally, low-field MRI systems typically cannot be made insensitive to their much stronger main field inhomogeneities, and hence suffer more from field imperfection artifacts.

Addressing magnetic field imperfections involves two main challenges: estimation and correction. Estimating concomitant fields is trivial, as it is an analytic function of the gradient waveform and the main magnet's field strength. Eddy current field estimation is more complex, varying across MRI systems and requiring scanner-specific characterization. Promising calibration based techniques and field measurement devices are commonly used to robustly estimate such eddy current fields. Main field inhomogeneities arise from both the main magnet's intrinsic inhomogeneity, as well as subject induced perturbations due to tissue susceptibility. While the latter are more challenging to estimate, many emerging calibration techniques suggest that such fields can be estimated from the raw data itself. As such, we will assume that sufficient estimation techniques have been performed, and focus this work primarily on correction techniques.

We define high-order fields as any field imperfections that require polynomials of degree d≥2 to describe the spatial variation. High-order magnetic field imperfections introduce high-order spatio-temporal phase variations during image encoding. When such high-order phase terms are present, the imaging model is no longer well approximated by a simple Fourier transform, making it difficult to directly use FFT-based techniques. A naive approach is to represent the linear forward model explicitly as a dense matrix, a technique referred to as the expanded encoding model, but this is computationally expensive. Instead, some approaches have modeled high-order spatio-temporal phase as a sum of separable spatial and temporal factors; we refer to this group of methods as spatio-temporal splitting. While spatio-temporal splitting significantly reduces computational cost compared to the dense matrix expanded encoding model, reconstruction time still scales linearly with the number of factors required to capture the high-order phase. To our knowledge, spatio-temporal splitting remains the current gold standard for efficiently modeling general magnetic field imperfections.

Our solution, High Order Fast Fourier Transform (HOFFT), builds upon and adapts a computational problem that arose decades ago when modeling non-Cartesian k-space sampling, where the FFT algorithm similarly could no longer be directly applied. The problem was resolved by the Non-Uniform Fast Fourier Transform (NUFFT) algorithm, which combines an apodized, oversampled FFT with compact kernel interpolation to efficiently model non-Cartesian sampling. NUFFTs enabled fast reconstruction across MRI, CT, and many other imaging modalities. The NUFFT algorithm was designed to model linear phase Fourier harmonics that describe a sample's deviation from the nearest Cartesian grid point. The present approach is to modify the NUFFT algorithm, and utilize the a compact interpolation kernel framework along with extra spatial factors to model both non-Cartesian linear phase Fourier harmonics as well as high-order phase functions. In essence, the method models high-order phase using modified FFT operators, and hence we refer to it as high order FFT (HOFFT) for short. In comparison to the gold standard spatio-temporal splitting techniques, HOFFT is designed to achieve a more favorable tradeoff between the extra computation needed to model high-order phase and the accuracy of the model.

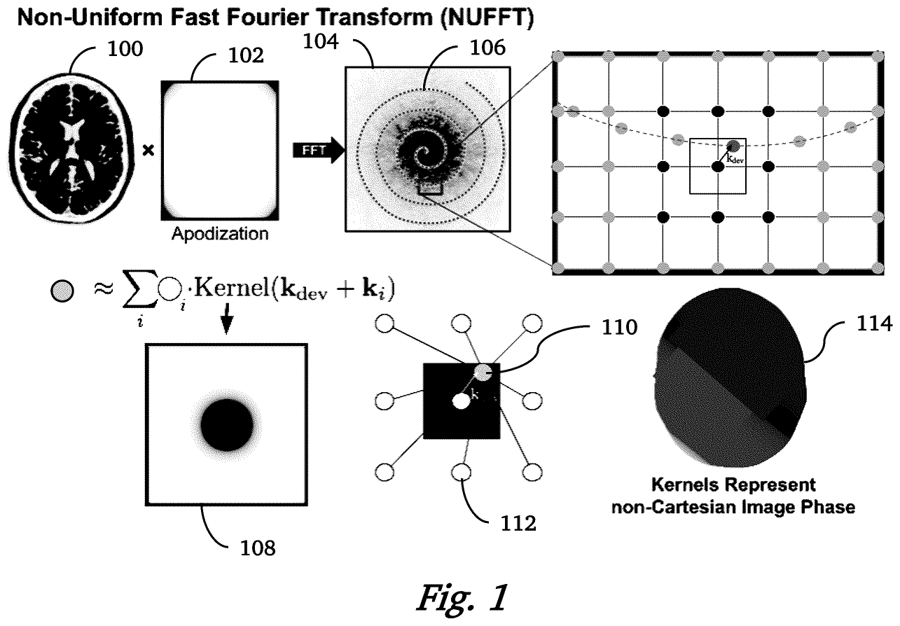

FIG. 1 shows a convolutional NUFFT pipeline. The image 100 gets multiplied by an apodization function 102, and then an oversampled FFT is performed to produce k-space data 104. To get the desired spiral 106 from Cartesian k-space samples, a compact kernel 108 (3×3 in this case) is used to linearly synthesize arbitrary points k 110 from grid-point neighbors z_{grid} (e.g., point 112) using the Kasier Bessel kernel. The kernel represents non-Cartesian linear image phase 114.

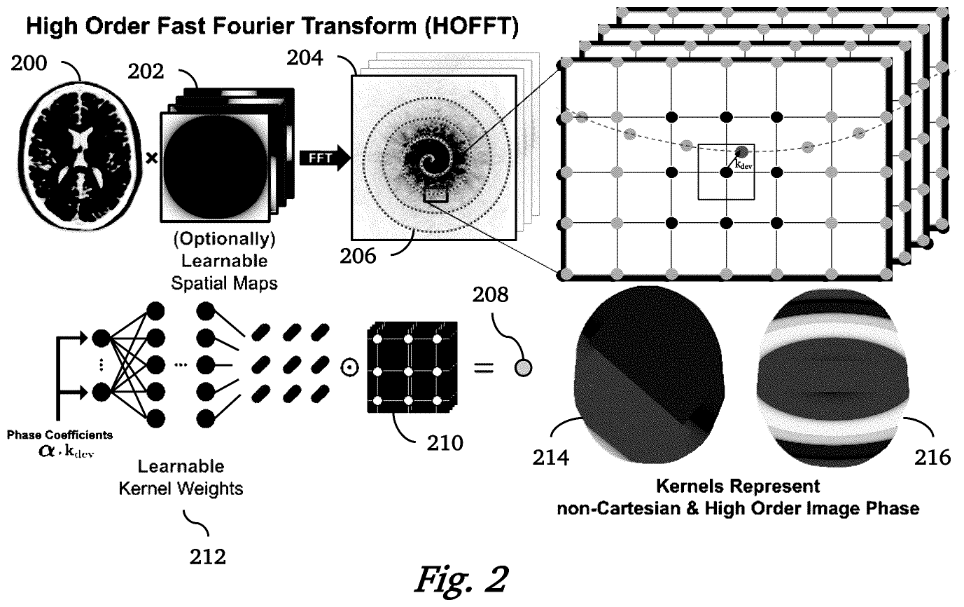

FIG. 2 shows a HOFFT pipeline. The image 200 gets multiplied by L=4 spatial weighting functions 202, and then an oversampled FFT is performed to obtain k-space data 204. To get the desired points k 208 in the spiral 206 (with higher order phase) from Cartesian k-space points z_{grid} 210, a compact kernel (3×3 in this case) is used to linearly synthesize the desired points k 208 from neighboring Cartesian k-space points z_{grid} 210.

A learned INR 212 is used to query the corresponding linear combination weights. The HOFFT kernel represents both non-Cartesian linear phase 214 and high order non-linear image phase 216.

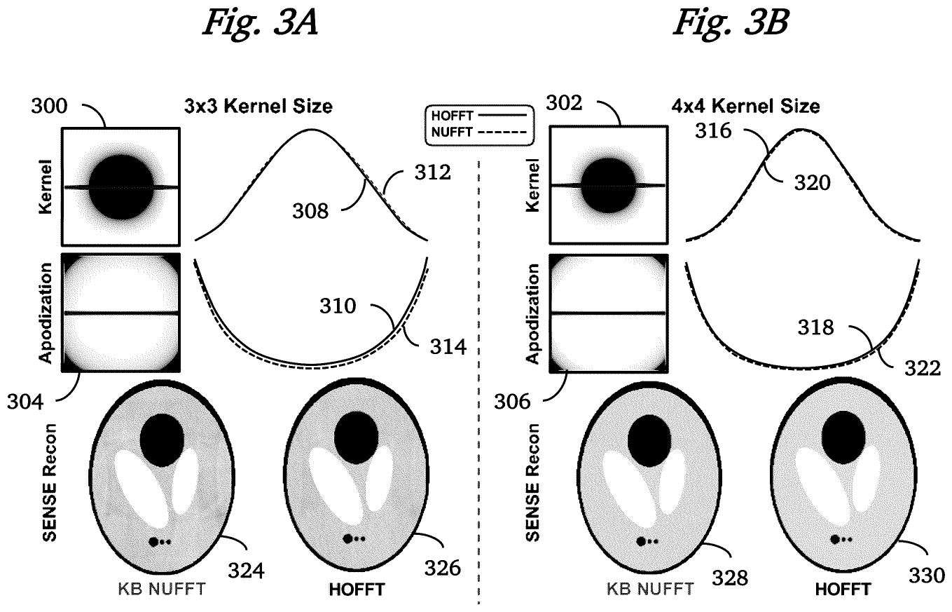

FIG. 3A shows 3×3 gridding kernel 300 and corresponding apodization 304 learned using the HOFFT framework. The graphs compare the HOFFT kernel and apodization functions 308 and 310 against the Kaiser Bessel (KB) NUFFT kernel and apodization functions 312 and 314. Similarly, FIG. 3B shows 4×4 gridding kernel 302 and corresponding apodization 306 learned using the HOFFT framework. The graphs compare the HOFFT kernel and apodization functions 316 and 318 against the Kaiser Bessel (KB) NUFFT kernel and apodization functions 320 and 322. In both cases, the grid oversampling was set to 1.25×. For the 3×3 CG-SENSE reconstructions, the learned HOFFT kernels resulted in an image 326 with less image artifacts than the NUFFT image 324. For the 4×4 CG-SENSE reconstructions, the learned HOFFT kernels resulted in an image 330 similar to the NUFFT image 328 generated with analytical KB kernels.

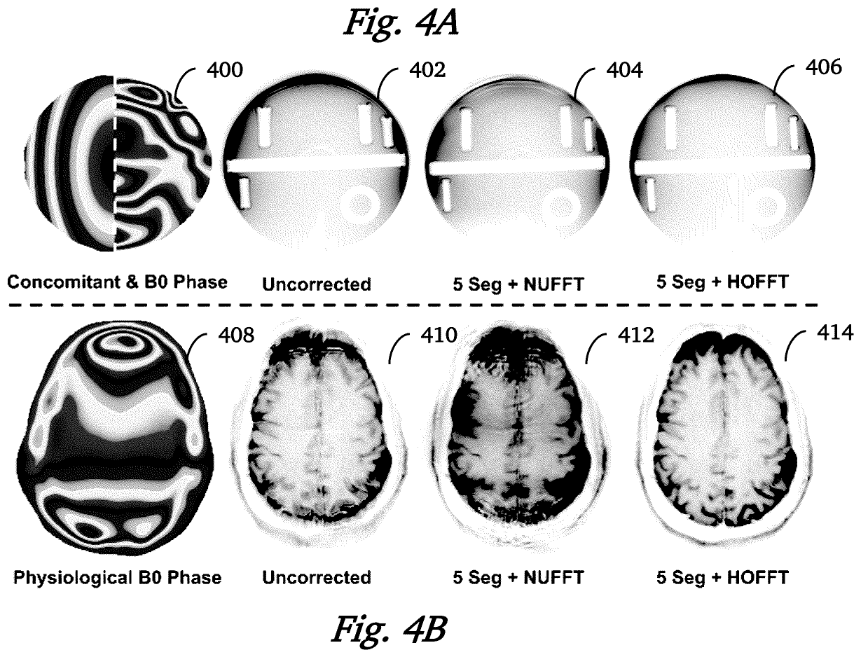

FIG. 4A shows spiral phantom measurements acquired in the presence of a concomitant and B₀ fields, yielding a spatio-temporal phase pattern 400. The measurements include uncorrected reconstructions 402, reconstructions with 5 time-segments using optimal least squares interpolators and NUFFT kernels 404, and 5 time-segments using synergetic 9×9 HOFFT kernels 406. FIG. 4B shows spiral in-vivo measurements are acquired in the presence of a physiologically induced field imperfection, yielding a physiological phase pattern 408. The measurements include uncorrected reconstructions 410, reconstructions with 5 time-segments using optimal least squares interpolators and NUFFT kernels 412, and 5 time-segments using synergetic 9×9 HOFFT kernels 414.

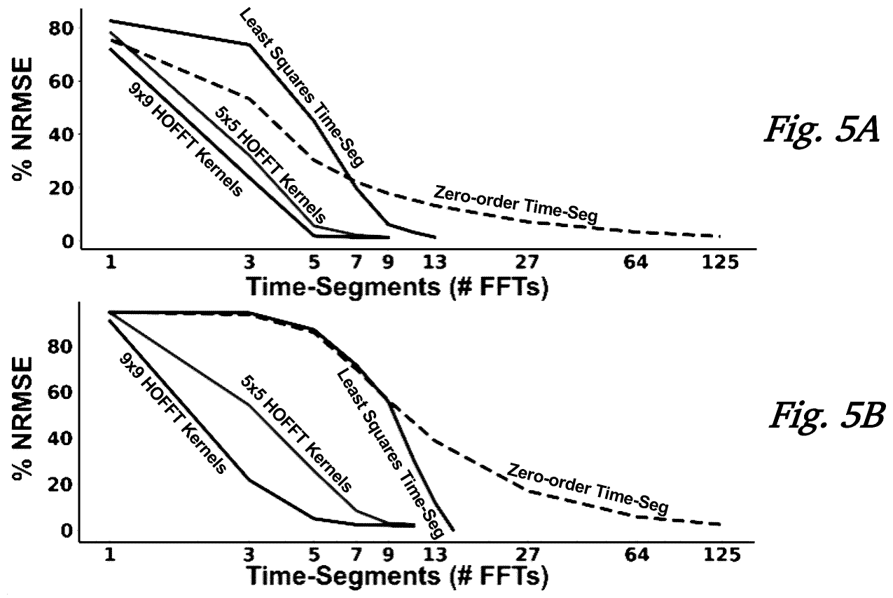

FIG. 5A shows graphs of normalized root mean squared error (NRMSE) versus the number of time-segments for spiral phantom measurements acquired in the presence of a concomitant and B₀ fields as in FIG. 4A. FIG. 5B shows graphs of normalized root mean squared error (NRMSE) versus the number of time-segments for spiral in-vivo measurements are acquired in the presence of a physiologically induced field imperfection as in FIG. 4B. Reconstructions with 100 least-squares optimal time segments are used as ground truth images. Zero order interpolators (dashed lines) and optimal least squares interpolators (solid) use 5×5 NUFFT kernels. 5×5 and 9×9 HOFFT kernels are learned for each number of time-segments.

### Theory

Throughout the theory section, we perform our analysis in d spatial dimensions and will commonly reference the following symbols

| | |
|---|---|
| d | number of spatial dimensions |
| Nᵢ | number of signal grid points for dimension i |
| N | $total number of signal samples N = {\prod }_{i = 1}^{d} {N}_{i}$ |
| M | number of k-space samples |
| σ | grid oversampling factor [symbol] ∈ [1, ∞) |
| Wᵢ | kernel width in samples for dimension i |
| W | $total number of kernel samples K = {\prod }_{i = 1}^{d} {W}_{i}$ |
| r | $spatial coordinate vector ∈ {ℝ}^{d} , {r}_{i} ∈ [ - \frac{1}{2} , + \frac{1}{2} ]$ |
| k | $Fourier coordinate vector ∈ {ℝ}^{d} , {k}_{i} ∈ [ - \frac{{N}_{i}}{2} , \frac{{N}_{i}}{2} ]$ |

Furthermore, we assume that the spatial signal of interest x(r) has finite support over the centered unit hyper-cube

$$( x ( r ) = 0 if \vert {r}_{i} \vert \geq \frac{1}{2} ) ,$$

which implies that Nyquist sampling occurs at integer Fourier grid coordinates. Our analysis will assume that the continuous space r and time t variables are discretized into N uniformly spaced spatial (r₁, . . . , r_{N}) and M uniformly spaced temporal (t₁, . . . , t_{M}) points.

We first provide a technical description of how the NUFFT algorithm works and how classical techniques model field imperfections. We then describe how our HOFFT approach improves field imperfection models, which combines ideas from both the NUFFT and classical field imperfection models. Finally, we describe an algorithm that performs the HOFFT decomposition efficiently.

### The NUFFT Based MRI Forward Model

The MRI signal y(t)∈ [symbol] is related to the underlying spatial signal x(r)∈ [symbol] according to

y(t)=∫ᵣx(r)e^{-j2πr·k(t)}dr, (1)

where k(t) is the time-varying non-Cartesian k-space trajectory. Naively discretizing the above continuous equation results in a dense matrix, which is not computationally efficient, and hence a NUFFT is preferred. In the NUFFT literature it is common to introduce an oversampling factor v, which is equivalent to zero padding x(r) so that the support increases σ-fold in each spatial dimension. The k-space trajectory k(t) can then split into a sum of the nearest integer grid coordinates z_{grid}(t) and a deviation term k_{dev}(t) as follows:

$$k ( t ) = \frac{{z}_{grid} ( t ) + {k}_{dev} ( t )}{σ} , \qquad ( 2 )$$

$$where$$

$${z}_{grid} ( t ) ∈ {[ - \frac{σ N}{2} , \frac{σ N}{2} ]}^{d}$$

are integer Cartesian coordinates on a σ-oversampled grid and

$${k}_{dev} ( t ) ∈ {[ - \frac{1}{2} , \frac{1}{2} ]}^{d}$$

are the deviations from the nearest Cartesian coordinates. The integer Cartesian coordinates z_{grid}(t) can be computed according to z_{grid}(t)=round(σ·k(t)). Note that if k_{dev}(t)=0 for all t, then a simple σ-oversampled FFT can be used for the forward model. For the non-trivial case of k_{dev}(t)≠0, an approximation is needed to construct an efficient forward model.

The NUFFT algorithm approximates the deviation phase term using a kernel model

$${e}^{- j 2 π r \cdot \frac{{k}_{dev}}{σ}} \approx {\sum }_{ω = 1}^{W} b ( r ) {h}_{NUFFT} ( ω , {k}_{dev} ) {e}^{- j 2 π r \cdot \frac{{z}_{ω}}{σ}} , \qquad ( 3 )$$

where h_{NUFFT}(w, k_{dev}) are the NUFFT kernel weights, b(r) is a spatial factor, and z_{w} ∈ [symbol] form a W₁ × . . . ×W_{d} rectangular kernel with unit spacing between adjacent kernel samples. It is common to use a kernel function, such as the Kaiser Bessel function, to model the kernel weights h_{NUFFT}(w, k_{dev}), and the reciprocal of the Fourier transform of the kernel function as the spatial factor b(r). Plugging equations (3) and (2) back into equation (1) yields the NUFFT forward model

$$\begin{matrix}y ( t ) \approx {\sum }_{ω = 1}^{W} {h}_{NUFFT} ( ω , {k}_{dev} ) {\int }_{r} x ( r ) b ( r ) {e}^{- j 2 π r \cdot ( \frac{{z}_{grid} ( t ) + {z}_{ω}}{σ} )} dr \\ \approx {\sum }_{ω = 1}^{W} {h}_{NUFFT} ( ω , {k}_{dev} ) ℱ {\{ x ( r ) b ( r ) \}}_{k = \frac{{z}_{grid} ( t ) + {z}_{ω}}{σ}} ,\end{matrix} \qquad ( 4 )$$

here we use [symbol] to denote the spatial Fourier Transform. Since the Fourier Transform is sampled at k-space coordinates on an u-oversampled grid, and the z_{w} form compact kernels, the above expression can be efficiently implemented using σ-oversampled FFTs and convolutions. This yields a computational complexity of

$$\text{?} ( σ Nd log ( σ N ) + κ WM ) , \qquad ( 5 )$$

where r is a computer hardware dependent weighting factor.

### Classical Field Imperfections Models in MRI

Most field imperfections in MRI manifest as an additional spatio-temporal phase term

$$y ( t ) = {\int }_{r} x ( r ) {e}^{- j 2 π r \cdot k ( t )} {\underbrace{{e}^{- j 2 π ϕ ( r ) \cdot α ( t )}}}_{Field Imperfection} dr . \qquad ( 6 )$$

φ(r) ∈ [symbol] are B spatial phase functions, and α(t) ∈ [symbol] are B corresponding temporal phase coefficients. We provide examples in the Appendix of how φ, α appear for different field imperfections. Since φ(r) is of higher order, i.e. it is not spatially linear, the NUFFT forward model cannot be directly applied. Note that if φ(r) had any components that were spatially linear, we would be able to add the corresponding α(t) components to the k-space trajectory k(t). Two classical techniques that approach this problem of modeling high order phase terms are expanded encoding and spatio-temporal splitting models.

### Expanded Encoding Model

The expanded encoding model completely avoids using Fourier operators in the forward model, and instead constructs the following dense matrix:

A_{m,n}=e^{-j2πr}^{ₙ}^{·k(t}^{ₘ}⁾e^{-j2πφ(r}^{ₙ}^{)·α(t}^{ₘ}⁾, (7)

where A ∈ [symbol] is the new forward model. The dense matrix computational complexity scales according to

[symbol]

(NM). (8)

Expanded encoding hence serves as the most accurate approach, since no high order phase approximations are made. This comes at the cost of being the least computationally efficient approach, which motivated spatio-temporal splitting techniques.

### Spatio-Temporal Splitting

In order to preserve the use of FFTs in the forward model, the high order phase term is decomposed into a separable sum of spatial and temporal factors

$${e}^{- j 2 π ϕ ( r ) \cdot α ( t )} \approx {\sum }_{l = 1}^{L} {b}_{l} ( r ) {h}_{split} ( l , t ) , \qquad ( 9 )$$

where b₁(r), . . . , b_{L}(r) are the learned spatial factors and h₁(t), . . . , hₛₚₗᵢₜ(l, t) the learned temporal factors. Assuming the above approximation is accurate, we can plug equations (3) and (9) into equation (6) resulting in the new forward model

$$\begin{matrix}y ( t ) \approx {\sum }_{l = 1}^{L} {h}_{split} ( l , t ) {\sum }_{w = 1}^{W} {h}_{NUFFT} ( w , {k}_{dev} ) {\int }_{r} x ( r ) {b}_{l} ( r ) {e}^{- j 2 π r \cdot {\underbrace{( \frac{{z}_{grid} ( t ) + {z}_{w}}{σ} )}}_{k}} dr \\ \approx {\sum }_{l = 1}^{L} {\sum }_{w = 1}^{W} {h}_{split} ( l , t ) {h}_{NUFFT} ( w , {k}_{dev} ) ℱ {\{ x ( r ) {b}_{l} ( r ) \}}_{k = \frac{{z}_{grid} ( t ) + {z}_{w}}{σ}}\end{matrix} . \qquad ( 10 )$$

Similar to equation (1), the Fourier Transform is sampled at k-space coordinates on an σ-oversampled grid, and the z_{w} form compact kernels, and hence the above expression can be efficiently implemented using v-oversampled FFTs and convolutions. This results in the following computational complexity

[symbol]

(L·(σNd log(σN)+κWM)). (11)

From the above equation, we can conclude that if L is small in comparison to min(N, M), then the spatio-temporal splitting complexity is desired compared to the expanded encoding complexity (8). Spatio-temporal splitting incurs an L-fold computational penalty compared to the case with no field imperfections (5). Spatio-temporal splitting techniques include time segmentation, multi frequency interpolation, and SVD based approaches. All of the aforementioned methods require solving a small optimization problem to estimate the learned spatial factors b₁(r), . . . , b_{L}(r) and the learned temporal factors hₛₚₗᵢₜ(1, t), . . . , hₛₚₗᵢₜ(L, t). We have developed the HOFFT model to achieve a better tradeoff between the number of factors L and the model accuracy.

### HOFFT Model

HOFFT models higher order (and non-Cartesian) phases using efficient FFT and compact kernel interpolation operators. Suppose we are given k(t) ∈ [symbol] , φ(r) ∈ [symbol] , α(t) ∈ [symbol] . We break HOFFT down into three key steps:
1. Combining Non-Cartesian Deviations into φ, α
   Similar to the NUFFT model, we split the k-space trajectory according to (2). We then view the k-space trajectory grid deviations as an additional ‘imperfection’, and append the deviation term onto the existing φ(r), α(t) imperfections:

\tilde{φ}(r)=(φ(r),r)∈

[symbol]

\tilde{α}(t)=(α(t),k_{dev}(t))∈

[symbol]

\tilde{B}=B+d.
Here \tilde{φ}(r), \tilde{α}(t) are combined coefficients representing both non-Cartesian deviations and higher order phase terms.
2. Perform HOFFT Decomposition
   We now find bₗ(r), h_{HOFFT}(l, w, t) such that

$${e}^{- j 2 π \tilde{ϕ} ( r ) \cdot \tilde{α} ( t )} \approx {\sum }_{l = 1}^{L} {\sum }_{w = 1}^{W} {h}_{HOFFT} ( l , w , t ) {b}_{l} ( r ) {e}^{- j 2 π r \cdot \frac{{z}_{w}}{σ}} . \qquad ( 12 )$$

Similar to the NUFFT model, the HOFFT model uses a W₁ × . . . ×W_{d} convolutional kernel, which allows Fourier harmonics e^{-j2πr·z}^{_{w}}, to assist in reducing approximation error. Unlike the NUFFT model, there are L unique temporally varying HOFFT kernel weights, each having a corresponding spatial function bₗ(r). Note that classical spatiotemporal splitting approaches factorized h_{HOFFT}(l, W, t)=hₛₚₗᵢₜ(l, t)h_{NUFFT}(w, k_{dev}(t)) independently, where the factor dimension ‘l’ was responsible for modeling high order phase, and the kernel dimension ‘w’ for modeling non-Cartesian linear phase. Instead, the HOFFT model learns temporal functions h_{HOFFT}(l, w, t) that model higher order and non-Cartesian linear phase over both the kernel and factor dimensions jointly with spatial factors bₗ(r).
3. Assemble Forward Model
   We can now apply the HOFFT decomposition from equation (12) back to the signal equation (6) to obtain the HOFFT forward model

$$\begin{matrix}y ( t ) \approx {\sum }_{l = 1}^{L} {\sum }_{w = 1}^{W} {h}_{HOFFT} ( l , w , t ) {\int }_{r} x ( r ) {b}_{l} ( r ) {e}^{- j 2 π r \cdot {\underbrace{( \frac{{z}_{grid} ( t ) + {z}_{w}}{σ} )}}_{k}} dr \\ \approx {\sum }_{l = 1}^{L} {\sum }_{w = 1}^{W} {h}_{HOFFT} ( l , w , t ) ℱ {\{ {b}_{l} ( r ) x ( r ) \}}_{k = \frac{{z}_{grid} ( t ) + {z}_{w}}{σ}}\end{matrix} . \qquad ( 13 )$$

In contrast to the classical spatio-temporal splitting approach, the kernels here change along the decomposition dimension l. The computational complexity of HOFFT is identical to that of the spatio-temporal splitting approach in (11), while offering improved accuracy.

### The HOFFT Decomposition Algorithm

We'd like to re-write the HOFFT decomposition (12) as a discrete optimization problem. To do so, we define the following matrices and a linear operator

Φ_{m,n}:=e^{-j2π\tilde{φ}(r}^{ₙ}^{)·\tilde{α}(t}^{ₘ}⁾ (14)

B_{l,n}:=bₗ(rₙ) (15)

Hₘ,(l+Lw):=h_{HOFFT}(l,w,tₘ) (16)

$${E ( B )}_{( l + Lw ) n} := {b}_{l} ( {r}_{n} ) {e}^{- j 2 π {r}_{n} \cdot \frac{{z}_{w}}{σ}} , \qquad ( 17 )$$

where Φ∈ [symbol] , B∈ [symbol] , H∈ [symbol] , E: [symbol] → [symbol] . Performing the HOFFT decomposition is then equivalent to finding a solution to the following optimization problem

$${min}_{H , B} {‖ HE ( B ) - Φ ‖}_{F}^{2} . \qquad ( 18 )$$

Although the optimization problem above is non-convex, it is bi-convex which motivates using an alternating least squares (ALS) algorithm:

$$\begin{matrix}{H}^{( k + 1 )} = {arg min}_{H} {‖ HE ( {B}^{( k )} ) - Φ ‖}_{F}^{2} \\ {B}^{( k + 1 )} = {arg min}_{B} {‖ {H}^{( k + 1 )} E ( B ) - Φ ‖}_{F}^{2} .\end{matrix} \qquad ( 19 )$$

The Appendix contains the solutions to the above equations in terms of high order phase integrals. We initialize B⁽⁰⁾ according to a k-means clustering procedure on the α(t) coefficients. Suppose that the L centroids returned by k-means on α(t) are β₁, . . . , β_{L}. Then, we initialize the spatial factors according to

$${B}_{l , n}^{( 0 )} = {e}^{- j 2 π ϕ ( {r}_{n} ) \cdot {β}_{l}} .$$

This initialization strategy is a variant of what is commonly referred to as ‘time segmentation’ in the literature.

### Methods

### Efficient Implementation Details

### Spatial and Temporal Downsampling

We can do better by spatially down-sampling the high order phase coefficients, and instead use N′<N spatial samples for the decomposition step in (12). This works quite well in practice, since the phase basis functions φ(r) are often spatially smooth. The temporal dimensions can also be substantially reduced by performing the ALS algorithm in (19) on K<M representative temporal coefficients β

### Appendix

### Common φ, α in MRI

Main Field Inhomogeneities: The source of such imperfections are a combination of the main magnet's intrinsic inhomogeneity and a subject induced field perturbation due to tissue susceptibilities. This takes the form

φ(r)=B₀(r)

α(t)=t

B=1,

where B₀(r) is a high order static inhomogeneity map and t is simply the time passed since the start of data acquisition. B₀(r) is usually a higher order term, meaning that polynomials of degree d≥2 are required to describe it.

Concomitant Fields: According to Maxwell's equations, perfectly linear magnetic fields cannot exist without additional concomitant field terms. These take the form

$$\begin{matrix}ϕ ( r ) = ( {r}_{x}^{2} + {r}_{y}^{2} , {r}_{x} {r}_{z} , {r}_{y} {r}_{z} , {r}_{z}^{2} ) \\ α ( t ) = \overline{γ} {\int }_{0}^{t} ( {G}_{z}^{2} ( τ ) , {G}_{x} ( τ ) {G}_{z} ( τ ) , {G}_{y} ( τ ) {G}_{z} ( τ ) , {G}_{x}^{2} ( τ ) + {G}_{y}^{2} ( τ ) ) d τ \\ B = 4 ,\end{matrix}$$

where Gₓ, G_{y}, G_{z} are the gradient waveforms and γ̅ is the gyromagnetic ratio. All φ(r) are of higher order.

Eddy Current Fields: Rapidly switching gradient fields induce opposing eddy currents in conducting structures along the scanner. In most of the MR literature, these terms are usually captured with spherical harmonic bases

$$\begin{matrix}ϕ ( r ) = ( 1 , {r}_{x} , {r}_{y} , {r}_{z} , {r}_{x} {r}_{y} , … , {r}_{x}^{3} - 3 {r}_{x} {r}_{y}^{2} ) \\ α ( t ) = ( {α}_{0} ( t ) , {α}_{1} ( t ) , {α}_{2} ( t ) , {α}_{3} ( t ) , {α}_{4} ( t ) , … {α}_{15} ( t ) ) \\ B = 16.\end{matrix}$$

Here the spatial phase bases are known, and the temporal coefficients α(t) are measured or estimated using calibration techniques. The first four terms are not higher order, and hence they can be combined with the Fourier trajectory k(t) in (6), and the remaining terms are higher order.

Alternating Least Squares Update Rules. The first part of alternating least squares (ALS) requires solving (19) for the next kernel functions

$${h}_{l , w}^{( k + 1 )} ( t )$$

assuming the previous known spatial factors

$${b}_{l}^{( k )}$$

(r) yielding

$$\begin{matrix}{G}_{{l}_{1} + {Lw}_{1} , {l}_{2} + {Lw}_{2}}^{( k )} & = & {\int }_{r} {\overline{b}}_{{l}_{1}}^{( k )} ( r ) {b}_{{l}_{2}}^{( k )} ( r ) {e}^{+ j 2 π \frac{( {z}_{{w}_{1}} - {z}_{{w}_{2}} )}{σ} \cdot r} dr & ( 20 ) \\ {f}_{l , w}^{( k )} ( t ) & = & {\int }_{r} {\overline{{b}_{l}}}^{( k )} ( r ) {e}^{+ j 2 π \frac{{z}_{w}}{σ} \cdot r} {e}^{- j 2 π \tilde{ϕ} ( r ) \cdot \tilde{α} ( t )} dr & ( 21 ) \\ ⇒ [ \begin{matrix}{h}_{1 , 1}^{( k + 1 )} ( t ) \\ ⋮ \\ {h}_{L , W}^{( k + 1 )} ( t )\end{matrix} ] & = & {( {G}^{( k )} )}^{- 1} [ \begin{matrix}{f}_{1 , 1}^{( k )} ( t ) \\ ⋮ \\ {f}_{L , W}^{( k )} ( t )\end{matrix} ] . & ( 22 )\end{matrix}$$

The second part of ALS requires solving (19) for the next spatial factors

$${b}_{l}^{( k + 1 )} ( r ) ,$$

assuming the previous known kernel functions

$${h}_{l , w}^{( k + 1 )} ( t )$$

yielding

$$\begin{matrix}G {( r )}_{{l}_{1} , {l}_{2}}^{( k + 1 )} & = & {\sum }_{{w}_{1} = 1}^{W} {\sum }_{{w}_{2} = 1}^{W} {e}^{+ j 2 π \frac{{z}_{{w}_{1}} - {z}_{{w}_{2}}}{σ} \cdot r} {\int }_{t} {\overline{h}}_{{l}_{1} , {w}_{1}}^{( k + 1 )} ( t ) {h}_{{l}_{2} , {w}_{2}}^{( k + 1 )} ( t ) dt & ( 23 ) \\ {f}_{l}^{( k + 1 )} ( r ) & = & {\sum }_{w = 1}^{W} {e}^{+ j 2 π \frac{{z}_{w}}{σ} \cdot r} {\int }_{t} {\overline{h}}_{l , w}^{( k + 1 )} ( t ) {e}^{- j 2 π \tilde{ϕ} ( r ) \cdot \tilde{α} ( t )} dt & ( 24 ) \\ ⇒ [ \begin{matrix}{b}_{1}^{( k + 1 )} ( r ) \\ ⋮ \\ {b}_{L}^{( k + 1 )} ( r )\end{matrix} ] & = & {( {G ( r )}^{( k + 1 )} )}^{- 1} [ \begin{matrix}{f}_{1}^{( k + 1 )} ( r ) \\ ⋮ \\ {f}_{L}^{( k + 1 )} ( r )\end{matrix} ] . & ( 25 )\end{matrix}$$

1. A method for magnetic resonance imaging (MRI) comprising:
(a) performing by an MRI apparatus an MRI acquisition using a readout sequence to produce acquired k-space data at coordinates k(t);
(b) measuring by the MRI apparatus or field measurement equipment non-linear spatio-temporal phase coefficients α(t), φ(r);
(c) combining vector deviations k_{dev}(t) of the coordinates k(t) from nearest Cartesian grid points z_{grid}(t) with the measured non-linear spatio-temporal phase coefficients α(t), φ(r) to construct combined spatio-temporal phase coefficients \tilde{φ}(r), \tilde{α}(t);
(d) jointly training L time-varying kernel weights h_{HOFFT}(w, l, t) and their respective L spatial factors bₗ(r) to model the combined spatio-temporal phase coefficients \tilde{α}(t), \tilde{φ}(r);
(e) constructing a HOFFT forward model A_{HOFFT} relating an input image x(r) to the k-space data y_{HOFFT}(t), the constructing comprising:
(i) computing an oversampled FFT of the input image x(r) multiplied by all L spatial factors bₗ(r);
(ii) selecting grid points that are nearest to Cartesian grid points z_{grid}(t); and
(iii) performing a dot product between the L time-varying kernel weights h_{HOFFT}(w,, t) and the values at the selected grid points for each of the L spatial factors bₗ(r) to obtain high-order phase modeled k-space data y_{HOFFT}(t)=A_{HOFFT}{x(r)}; and
(f) solving a general linear inverse problem using A_{HOFFT} and the acquired k-space data to obtain a reconstructed MRI image.

2. The method of claim 1 wherein jointly training comprises minimizing a difference between estimated and true total high order and non-Cartesian linear phase, wherein the estimated phase is obtained by applying kernel weights to respective spatial factors.

3. The method of claim 1 wherein h_{HOFFT}(w, l, t), bₗ(r) are represented using any optimizable signal representation approach.

4. The method of claim 1 wherein jointly training comprises training an MLP with a stochastic gradient descent optimizers.

5. The method of claim 1 wherein jointly training comprises training a grid-based representation with an alternating least squares optimizer.
